(19) United States
(12) Patent Application Publication
(10) Pub. No.: US 2011/0108094 A1
(43) Pub. Date: May 12, 2011

(54) LAMINATED SHEET FOR SOLAR CELL AND SOLAR CELL MODULE USING THE SAME

(75) Inventors: Koichi Nishijima, Chiba (JP); Yasuki Shibata, Chiba (JP); Masanobu Sato, Tokyo (JP)

(73) Assignee: DU PONT-MITSUI POLYCHEMICALS CO., LTD., Minato-ku, Tokyo (JP)

(21) Appl. No.: 13/000,257

(22) PCT Filed: Jun. 26, 2009
(86) PCT No.: PCT/JP2009/061737

§ 371 Date: Dec. 20, 2010

(30) Foreign Application Priority Data
Jun. 26, 2008 (JP) 2008-166959
Mar. 27, 2009 (JP) 2009-080157

(51) Int. Cl. H01L 31/048; C09J 7/02; B32B 27/06

(52) U.S. Cl. 136/251; 428/355 CN; 428/345; 428/356

(57) ABSTRACT

Provided is a laminated sheet for solar cell having a back sheet base material including a fluoro-resin or a polyester resin, and a sealing material layer which includes an ethylene copolymer composition containing a copolymer of an ethylene and a polar monomer which has a polar group selected from a group consist of a carboxylic acid group and a group derived from a carboxylate and a dialkoxysilane having an amino group is laminated on a surface of the back sheet base material where a chemical treatment or a physical treatment for improving adhesiveness has been applied, by a melt extrusion lamination method. Thereby, a laminated sheet having excellent productivity and excellent interlayer adhesion strength between the back sheet and the sealing material is obtained.

### TECHNICAL FIELD

The present invention relates to a laminated sheet for solar cell which is used for fixing a solar cell element that constitutes a solar cell module, and a solar cell module including the laminated sheet.

### BACKGROUND ART

Hydroelectric power generation, wind power generation, photovoltaic power generation and the like, which can be used to attempt to reduce carbon dioxide or improve other environmental problems by using inexhaustible natural energy, have received much attention. Among these, photovoltaic power generation has seen a remarkable improvement in performance such as the power generation efficiency of solar cell modules, and an ongoing decrease in price, and national and local governments have worked on projects to promote the introduction of residential photovoltaic power generation systems. Thus, in recent years, the spread of photovoltaic power generation systems has advanced considerably.

Photovoltaic power generation directly converts solar energy to electric energy using a silicon cell semiconductor (solar cell element). The solar cell element as used herein undergoes a decrease in function thereof when directly brought into contact with air from the outside. Therefore, in general, a solar cell element is interposed between a sealing material and a transparent surface protective material (mainly, glass), and a rear surface protective material (a back sheet of, for example, a polyester-based resin, a fluoro-resin or the like), so as to provide buffering and to prevent incorporation of foreign materials or infiltration of, for example, moisture. In this case, the back sheet is required to have various performances such as electrical insulating property, flame retardancy, heat resistance, adhesiveness to the sealing material and weather resistance, in addition to the function of protecting the solar cell element from the external environment (such as rain, moisture or wind). Accordingly, investigations have been carried out on various materials and configurations to satisfy these performances.

As the back sheet, a sheet for sealing rear surface of the solar cell which uses a film of, for example, a polyester resin or a fluoro-resin having excellent electrical insulating property, has been used. When this film of a polyester resin or a fluoro-resin is used, there is a problem that the back sheet has a demerit of poor adhesiveness to the sealing material. There have been suggested, as methods for improving this adhesiveness, for example, a method of coating a easily adhesive coating layer that functions as a primer, on the back sheet (see, for example, Patent Document 1), and a method of subjecting the polyester film to a corona treatment (see, for example, Patent Document 2).

There have been numerous suggestions other than described above in regards to making the back sheet into a multilayer structure in order to improve the performance of the back sheet (see, for example, Patent Documents 3 to 7). In order to produce a solar cell module using such a laminated back sheet and a solar cell element, further a sealing material is needed. Furthermore, there is a demand for a further enhancement of the adhesion strength between the film of a polyester resin or a fluoro-resin that serves as a base material (base) and other performance improved layers in the laminated back sheet.
Patent Document 1: Japanese Patent Application Laid-Open (JP-A) No. 2007-48944
Patent Document 2: JP-A No. 2000-243999
Patent Document 3: PCT Japanese Translation Patent Publication No. 2008-546557
Patent Document 4: JP-A No. 2005-322681
Patent Document 5: JP-A No. 2006-179557
Patent Document 6: JP-A No. 2006-210557
Patent Document 7: JP-A No. 2007-150084

### DISCLOSURE OF INVENTION

### Problem to be Solved by the Invention

Solar cells require durability to maintain their performance over a long time period of about 20 years, and the reliability of a solar cell depends on the adhesiveness between the sealing material and the back sheet. However, when the adhesion strength between the sealing material and the back sheet markedly decreases, and delamination occurs under the effect of the decreased adhesion strength, moisture may pass through the delaminated site and permeate into the sealing material, causing problems such as reduced output power.

The evaluation of this durability is carried out by an acceleration test under a high temperature and high humidity environment (temperature: 85° C. and relative humidity: 85%), but under the current circumstances, the problem of lowering of the adhesiveness between the back sheet and the sealing material, which maintains long-term reliability, has not yet been solved.

When a solar cell module is produced, the production is achieved by the following two methods.

(1) A back sheet, a sealing material, a solar cell element, a sealing material, and a glass plate are stacked in this order, and the assembly is integrated by heating.

(2) A sealing material and a back sheet are stacked in order on the solar cell element-formed surface where a solar cell element has been formed directly on a glass plate, and the assembly is integrated by heating.

These methods all prepare separately a back sheet and a sealing material, and require the integration of these materials with other members including a solar cell element by simultaneously stacking them while performing cautious transport thereof and cautious positioning thereof.

Furthermore, places for storing (stocking) the respective members are also required. In addition to these, production facilities supplying the respective members are required, and a large installation place is required during the module production.

The invention was made under such circumstances. Under such circumstances, there is a need for a laminated sheet for solar cell which, in the conventional production field for solar cell modules, has significantly improved member maintenance or member handleability, contributes to an enhancement of productivity and simplification of production facilities, and has excellent interlayer adhesion strength between the back sheet and the sealing material. Furthermore, there is a need for a solar cell module having excellent durability.

### Means for Solving the Problem

Specific means for achieving the objects described above are as follows. Specifically, the invention relates to:

<1> A laminated sheet for solar cell having a back sheet base material including a fluoro-resin or a polyester resin, and a sealing material layer which includes an ethylene copolymer composition containing a copolymer of an ethylene and a polar monomer which has a polar group selected from a carboxylic acid group and a group derived from carboxylate, and a dialkoxysilane having an amino group is laminated on a surface of the back sheet base material where a chemical treatment or a physical treatment for improving adhesiveness has been applied, by a melt extrusion lamination method.

<2> The laminated sheet for a solar cell is preferably a laminated sheet for solar cell as described in <1>, wherein the chemical treatment includes coating of a two-liquid reaction type urethane resin-based anchor coating agent.

<3> The laminated sheet for a solar cell is preferably a laminated sheet for solar cell as described in <2>, wherein the urethane resin-based anchor coating agent is a two-liquid reaction type adhesive composition which includes a main agent containing a polyester urethane polyol and a curing agent containing an isocyanate compound.

<4> The laminated sheet for a solar cell is preferably a laminated sheet for solar cell as described in any one of the above <1> to <3>, wherein the physical treatment is a corona treatment.

<5> The laminated sheet for a solar cell is preferably a laminated sheet for solar cell as described in any one of the above <1> to <4>, wherein the copolymer of ethylene and a polar monomer is at least one of an ethylene-unsaturated carboxylic acid copolymer or an ionomer of an ethylene-unsaturated carboxylic acid copolymer.

<6> The laminated sheet for a solar cell is preferably a laminated sheet for solar cell as described in any one of the above <1> to <5>, wherein the dialkoxysilane is at least one of 3-aminopropylalkyldialkoxysilane or N2-(aminoethyl)-3-aminopropylalkyldialkoxysilane.

<7> The laminated sheet for a solar cell is preferably a laminated sheet for solar cell as described in any one of the above <1> to <6>, wherein a content ratio of the dialkoxysilane is 15 parts or less by mass with respect to 100 parts by mass of the copolymer of ethylene and a polar monomer.

<8> The laminated sheet for a solar cell is a laminated sheet for solar cell as described in any one of the above <5> to <7>, wherein the ethylene-unsaturated carboxylic acid copolymer is an ethylene-acrylic acid copolymer or an ethylene-methacrylic acid copolymer.

<9> The laminated sheet for a solar cell is a laminated sheet for solar cell as described in any one of the above <5> to <8>, wherein the ionomer is a zinc ionomer of an ethylene-unsaturated carboxylic acid copolymer.

<10> The laminated sheet for a solar cell is a laminated sheet for solar cell as described in any one of the above <5> to <9>, wherein the ionomer has a degree of neutralization with respect to acid groups in the ethylene-unsaturated carboxylic acid copolymer of 60% or less.

<11> The laminated sheet for a solar cell is a laminated sheet for solar cell as described in any one of the above <5> to <10>, wherein, in the ethylene-unsaturated carboxylic acid copolymer, a proportion of a constituent unit derived from an unsaturated carboxylic acid is 20% or less by mass with respect to a total mass of the copolymer.

<12> The laminated sheet for a solar cell is a laminated sheet for solar cell as described in any one of the above <1> to <11>, wherein the content of the dialkoxysilane is from 0.03 parts by mass to 12 parts by mass with respect to 100 parts by mass of the ethylene-polar monomer copolymer.

<13> The laminated sheet for a solar cell is preferably a laminated sheet for solar cell as described in any one of the above <1> to <12>, wherein the fluoro-resin is at least of a tetrafluoroethylene-ethylene copolymer, a tetrafluoroethylene-hexafluoropropylene copolymer, a tetrafluoroethylene-perfluoroalkyl vinyl ether copolymer, polychlorotrifluoroethylene, a chlorotrifluoroethylene-ethylene copolymer, polyvinyl fluoride, or polyvinylidene fluoride.

<14> The laminated sheet for a solar cell is preferably a laminated sheet for solar cell as described in any one of the above <1> to <13>, wherein the polyester resin is at least one of a polyethylene terephthalate (PET), a polyethylene naphthalate (PEN), a polybutylene terephthalate (PBT), or a polycyclohexanedimethanol terephthalate (PCT).

<15> A solar cell module including: a substrate on which sunlight enters; a solar cell element; and the laminated sheet for a solar cell as described in any one of the above <1> to <14>.

### Effect of the Invention

According to the invention, there is provided a laminated sheet for solar cell, which has significantly improved member maintenance or member handleability, in the conventional production field for solar cell modules, contributes to an enhancement of productivity and simplification of production facilities, and has excellent interlayer adhesion strength between the back sheet and the sealing material. Furthermore, according to the invention, there is provided a solar cell module having excellent durability.

### BEST MODE FOR CARRYING OUT THE INVENTION

Hereinafter, the laminated sheet for solar cell of the invention, and the solar cell module using this laminated sheet will be described in detail.

The laminated sheet for solar cell of the invention is constituted into a laminated structure having a back sheet base material including a fluoro-resin or a polyester resin, and a sealing material layer which includes an ethylene copolymer composition containing a copolymer of an ethylene and a polar monomer which has a polar group selected from a carboxylic acid group and a group derived from carboxylate, and a dialkoxysilane having an amino group is laminated on a surface of the back sheet base material where a chemical treatment or a physical treatment for improving adhesiveness has been applied, by a melt extrusion lamination method.

The invention is capable of providing a laminated sheet for solar cell in which the back sheet and the sealing material are integrated. Thereby, the laminated sheet for solar cell significantly improves the member maintenance or member handleability in the conventional production field for solar cell modules. That is, it is not necessary to carry out separate maintenance for the back sheet and the sealing material. During the module production, troublesome handling of the sealing material, which is prone to sag under its own weight due to the high flexibility thereof, is made easy. Particularly, in the method (2) for producing a solar cell module, innovative productivity improvement can be provided for the production of thin film type solar cell modules.

Furthermore, the invention is capable of performing high-speed integral molding of the back sheet and the sealing material by a melt lamination method, and exhibits strong interlayer adhesion strength, thus having excellent long-term durability.

Moreover, the invention is capable of providing a solar cell module having excellent durability since firm adhesion is achieved even with inorganic materials such as glass.

In the present invention, since a composition for sealing material formed from an ethylene copolymer composition containing a specific copolymer of a polar monomer and ethylene (hereinafter, may be indicated as an ethylene-polar monomer copolymer) and a specific alkoxysilane compound is used on the surface of the back sheet base material where a chemical treatment or a physical treatment that will be described below has been applied, lamination integration may be achieved at high speed by a melt lamination method.

As a result, the resulting laminated sheet has moisture resistance and water resistance, flexibility, and moldability during module production. Furthermore, the adhesiveness of the back sheet in a laminated structure including a substrate on which sunlight enters/solar cell element/back sheet, and more specifically, the adhesiveness to the member contacting with the sealing material surface of the laminated sheet when a structure including a substrate/solar cell element/sealing material/back sheet is obtained by providing the sealing material between the solar cell element and the back sheet, may be increased. Furthermore, more satisfactory adhesiveness is obtained, coupled with an effect of enhancing a heat resistance. Thereby, penetration of outside air, foreign materials, moisture and the like resulting from the interlayer delamination between the back sheet and the sealing material and the interlayer delamination of the sealing material and other members such as glass or the solar cell element, may be avoided, so that a decrease in the cell functions is suppressed, and the long-term durability performance of the solar cell is enhanced.

The ethylene-polar monomer copolymer according to the invention is a polymer obtained by copolymerizing at least ethylene and a polar monomer as copolymerization components, and as necessary, another monomer may be copolymerized as well.

The polar monomer is an unsaturated monomer having an unsaturated group and at least one polar group selected from a carboxylic acid group and a carboxylate-derived group, and a single kind may be used alone, or a mixture of two or more kinds may be used. The unsaturated group is preferably an addition polymerizable group, and more preferably a group containing an ethylenically unsaturated bond. The carboxylic acid group and the carboxylate-derived group are preferable in terms of adhesiveness, as compared with polar groups other than these.

Examples of the polar monomer having a carboxylic acid group and a carboxylate-derived group (hereinafter, may be collectively referred to as “unsaturated carboxylic acid”) include acrylic acid, methacrylic acid, fumaric acid, itaconic acid, maleic acid, maleic acid monoester (monomethyl maleate, monoethyl maleate, and the like), and salts thereof with monovalent metals (for example, lithium, potassium and sodium) or salts thereof with polyvalent metals (for example, magnesium, calcium and zinc).

Among these, acrylic acid and methacrylic acid are preferred in view of the reactivity of the carboxylic acid group.

Particularly preferable examples of the ethylene-polar monomer copolymer include an ethylene-acrylic acid copolymer and an ethylene-methacrylic acid copolymer, in view of adhesiveness.

When the polar monomer is a metal salt of an unsaturated carboxylic acid, this ethylene-polar monomer copolymer is known as an ionomer.

Copolymers described above may be used as the ethylene-unsaturated carboxylic acid copolymer which serves as the base of the ionomer of an ethylene-unsaturated carboxylic acid copolymer. Examples of the metal species include alkali metals such as lithium and sodium, and polyvalent metals such as calcium, magnesium, zinc and aluminum. Advantages of using these ionomers include high transparency and high storage elastic modulus at high temperature. The degree of neutralization is, for example, desirably 80% or less, but when adhesiveness and the like are considered, an excessively high degree of neutralization is not desirable. An ionomer having a degree of neutralization of, for example, 60% or less, and particularly 30% or less, is preferable. The lower limit of the degree of neutralization is desirably 5%.

The ethylene-polar monomer copolymer which serves as the base of the ionomer is preferably an ethylene-acrylic acid copolymer or an ethylene-methacrylic acid copolymer. A particularly preferable metal species is zinc. Since a zinc ionomer contains a zinc ion as the metal ion, the ionomer is particularly excellent in weather resistance, and generation of gel-like substances and foams during the sheet production process is also largely expressed as compared with an ionomer including another metal ion such as Na, so that stability during the sheet production is enhanced.

The proportion of the “constituent unit derived from a polar monomer” in the ethylene-polar monomer copolymer is 1% or more by mass with respect to the total mass of the copolymer. A proportion of 1% by mass or more implies a meaningful content, and when this proportion is less than 1% by mass, the adhesiveness of the resulting copolymer is decreased, and furthermore, the durability of the solar cell is decreased. This is suitable particularly in the case of an ethylene-unsaturated carboxylic acid copolymer or an ionomer thereof, and it is preferable that the proportion of the constituent unit derived from an unsaturated carboxylic acid is 1% or more by mass with respect to the total mass of the copolymer.

Furthermore, if the proportion of the constituent unit derived from an unsaturated carboxylic acid in the copolymer is increased, a copolymer with superior transparency may be obtained, but it is likely to have problems with low melting point or increased hygroscopic properties. Therefore, the proportion of the constituent unit derived from an unsaturated carboxylic acid is preferably 20% by mass or less, and more preferably 15% or less by mass, with respect to the total mass of the copolymer.

The melting point of the ethylene-polar monomer copolymer is preferably 55° C. or higher, more preferably 60° C. or higher, and particularly preferably 70° C. or higher. When the melting point of the ethylene-polar monomer copolymer or an ionomer thereof is 55° C. or higher, the copolymer or ionomer has satisfactory heat resistance, and when the copolymer or ionomer is used in the sealing material for sealing a solar cell element, deformation of the sealing material due to temperature increase during the use in a solar cell is prevented. Thus, problems such as that when the solar cell module is produced by a heating pressing method, the sealing material flows out more than necessary causing the occurrence of burrs, may be avoided. Furthermore, it is not necessary to deliberately use a crosslinking agent to increase the heat resistance.

Considering the molding processability, mechanical strength and the like, the ethylene-polar monomer copolymer according to the invention preferably has a melt flow rate (MFR; hereinafter, the same) according to JIS K7210-1999 (190° C., under a load of 2160 g) of 1 g/10 min to 100 g/10 min, and particularly preferably 5 g/10 min to 50 g/10 min.

The ethylene-polar monomer copolymer may have a constituent unit derived from a monomer other than ethylene and the “polar monomer having a polar group selected from a carboxylic acid group and a carboxylate-derived group.” The ethylene-polar monomer copolymer may be copolymer that a vinyl ester or an alkyl ester of (meth)acrylic acid or the like are copolymerized as the other monomer, and an effect of imparting flexibility is obtained. The proportion of the other monomer in the copolymer in this case may be appropriately selected as long as the effects of the invention are not impaired.

The ethylene-polar monomer copolymer may be obtained by radical copolymerization under high temperature and high pressure. Furthermore, the ionomer of the ethylene-polar monomer copolymer may be obtained by reacting an ethylene-polar monomer copolymer and a metal compound.

Examples of the “dialkoxysilane having an amino group” that is incorporated into the ethylene copolymer composition according to the invention include N2-(aminoethyl)-3-aminopropylalkyldialkoxysilanes such as N2-(aminoethyl)-3-aminopropylmethyldimethoxysilane and N2-(aminoethyl)-3-aminopropylmethyldiethoxysilane; 3-aminopropylalkyldialkoxysilanes such as 3-aminopropylmethyldimethoxysilane and 3-aminopropylmethyldiethoxysilane; N-phenyl-3-aminopropylmethyldimethoxysilane, and N-phenyl-3-aminopropylmethyldiethoxysilane.

Among these, as the dialkoxysilane, N2-(aminoethyl)-3-aminopropylalkyldialkoxysilane (more preferably, with an alkyl moiety having 1 to 3 carbon atoms) or 3-aminopropylalkyldialkoxysilane (more preferably with an alkyl moiety having 1 to 3 carbon atoms) is preferred. Among them, particularly N2-(aminoethyl)-3-aminopropylmethyldimethoxysilane, N2-(aminoethyl)-3-aminopropylmethyldiethoxysilane, 3-aminopropylmethyldimethoxysilane, and 3-aminopropylmethyldiethoxysilane are preferred. In particular, N2-(aminoethyl)-3-aminopropylmethyldimethoxysilane is used with preference because it is easily available from industrial viewpoints.

When a trialkoxysilane is used as a silane coupling agent in the ethylene copolymer composition, the viscosity increase is large, the composition is likely to turn into a gel-like matter, and the adhesiveness decreases relatively rapidly during storage. However, when a dialkoxysilane is used as a silane coupling agent as in the invention, viscosity increase or gelation during the lamination process is suppressed, and the composition is stabilized and maintains adhesiveness. Thus, the adhesion processing to the back sheet can be performed in a stable manner.

The dialkoxysilane having an amino group is incorporated preferably at a proportion of 15 parts or less by mass, more preferably 0.03 parts by mass to 12 parts by mass, and particularly preferably 0.05 parts by mass to 12 parts by mass, with respect to 100 parts by mass of the ethylene-polar monomer copolymer according to the invention, from the viewpoints of the effect of improving the adhesiveness to the base materials (including the back sheet as well as a substrate such as a glass on which sunlight enters) that include a solar cell element therebetween, and from the viewpoints of stability such as suppression of the generation of, for example, a gel-like matter during sheet molding.

When the amount of the dialkoxysilane having an amino group is 15 parts or less by mass, good adhesiveness may be obtained, and sheet molding can be stably achieved by suppressing the generation of a gel-like matter.

It is also effective, in view of preventing the deterioration of the sealing material due to ultraviolet rays in sunlight, to incorporate at least one weather resistant stabilizer such as an antioxidant, a photostabilizer or an ultraviolet absorber, into the ethylene copolymer composition of the invention.

Suitable examples of the ultraviolet absorber include benzophenone-based agents such as 2-hydroxy-4-methoxybenzophenone, 2,2′-dihydroxy-4-methoxybenzophenone, 2-hydroxy-4-methoxy-2-carboxybenzophenone, and 2-hydroxy-4-n-octoxybenzophenone; benzotriazole-based agents such as 2-(2′-hydroxy-3′,5′-di-tertiary-butylphenyl)benzotriazole, 2-(2′-hydroxy-5-methylphenyl)benzotriazole, and 2-(2′-hydroxy-5-tertiary-octylphenyl)benzotriazole; and salicylic acid ester-based agents such as phenyl salicylate, and p-octylphenyl salicylate.

For example, various hindered phenol-based and phosphite-based agents may be suitably used as the antioxidant. Specific examples of the hindered phenol-based antioxidant include 2,6-di-t-butyl-p-cresol, 2-t-butyl-4-methoxyphenol, 3-t-butyl-4-methoxyphenol, 2,6-di-t-butyl-4-ethylphenol, 2,2′-methylenebis(4-methyl-6-t-butylphenol), 2,2′-methylenebis(4-ethyl-6-t-butylphenol), 4,4′-methylenebis(2,6-di-t-butylphenol), 2,2′-methylenebis[6-(1-methylcyclohexyl)-p-cresol], bis[3,3-bis(4-hydroxy-3-t-butylphenyl)butyric acid]glycol ester, 4,4′-butylidenebis(6-t-butyl-m-cresol), 2,2′-ethylidenebis(4-sec-butyl-6-t-butylphenol), 2,2′-ethylidenebis(4,6-di-t-butylphenol), 1,1,3-tris(2-methyl-4-hydroxy-5-t-butylphenyl)butane, 1,3,5-tris(3,5-di-t-butyl-4-hydroxybenzyl)-2,4,6-trimethylbenzene, 2,6-diphenyl-4-octadecyloxyphenol, tetrakis[methylene-3-(3,5-di-t-butyl-4-hydroxyphenyl) propionate]methane, n-octadecyl-3-(3,5-di-t-butyl-4-hydroxyphenyl)propionate, 4,4′-thiobis(6-t-butyl-m-cresol), tocopherol, 3,9-bis[1,1-dimethyl-2-[β-(3-t-butyl-4-hydroxy-5-methylphenyl)propionyloxy]ethyl]2,4,8,10-tetraoxaspiro[5,5]undecane, and 2,4,6-tris(3,5-di-t-butyl-4-hydroxybenzylthio)-1,3,5-triazine.

Specific examples of the phosphite-based antioxidant include 3,5-di-t-butyl-4-hydroxybenzylphosphanate dimethyl ester, ethyl bis(3,5-di-t-butyl-4-hydroxybenzylphosphonate, and tris(2,4-di-t-butylphenyl)phosphanate.

As the above-mentioned photostabilizer, for example, hindered amine-based agents can be suitably used. Specific examples of the hindered amine-based photostabilizers include 4-acetoxy-2,2,6,6-tetramethylpiperidine, 4-stearoyloxy-2,2,6,6-tetramethylpiperidine, 4-acryloyloxy-2,2,6,6-tetramethylpiperidine, 4-benzoyloxy-2,2,6,6-tetramethylpiperidine, 4-cyclohexanoyloxy-2,2,6,6-tetramethylpiperidine, 4-(o-chlorobenzoyloxy)-2,2,6,6-tetramethylpiperidine, 4-(phenoxyacetoxy)-2,2,6,6-tetramethylpiperidine, 1,3,8-triaza-7,7,9,9-tetramethyl-2,4-dioxo-3-n-octylspiro[4,5]decane, bis(2,2,6,6-tetramethyl-4-piperidyl) sebacate, bis(2,2,6,6-tetramethyl-4-piperidyl)terephthalate, bis(1,2,2,6,6-pentamethyl-4-piperidyl)sebacate, tris(2,2,6,6-tetramethyl-4-piperidyl)benzene-1,3,5-tricarboxylate, tris(2,2,6,6-tetramethyl-4-piperidyl)-2-acetoxypropane-1,2,3-tricarboxylate, tris(2,2,6,6-tetramethyl-4-piperidyl) 2-hydroxypropane-1,2,3-tricarboxylate, tris(2,2,6,6-tetramethyl-4-piperidyl)triazine-2,4,6-tricarboxylate, tris(2,2,6,6-tetramethyl-4-piperidine) phosphite, tris(2,2,6,6-tetramethyl-4-piperidyl)butane-1,2,3-tricarboxylate, tetrakis(2,2,6,6-tetramethyl-4-piperidyl)propane-1,1,2,3-tetracarboxylate, and tetrakis(2,2,6,6-tetramethyl-4-piperidyl)butane-1,2,3,4-tetracarboxylate.

It is effective to incorporate the weather resistant stabilizers in an amount preferably in the range of 5 parts or less by mass, and particularly in the range of 0.1 parts by mass to 3 parts by mass, with respect to 100 parts by mass of the ethylene-polar monomer copolymer.

In addition to these, the ethylene copolymer composition of the invention can be mixed with any other additives as long as the purpose of the invention are not impaired. As the other additives, various known additives can be used, and examples thereof include a pigment, a dye, a lubricant, a discoloration preventing agent, an anti-blocking agent, a foaming agent, an auxiliary foaming agent, a crosslinking agent, a crosslinking aid, an inorganic filler, and a flame retardant.

As the discoloration preventing agent, a fatty acid salt of a metal such as cadmium or barium may be used.

If the laminated sheet for solar cell of the invention is not required to have transparency, a pigment, a dye, an inorganic filler and the like may be incorporated for the purpose of coloration, enhancing the power generation efficiency and the like. Examples thereof include white pigments such as titanium oxide and calcium carbonate; blue pigments such as ultramarine; black pigments such as carbon black, as well as glass beads and a light diffusing agent. According to the invention, when an inorganic pigment such as titanium oxide in particular is incorporated together with the ethylene-polar monomer copolymer, it is preferable from the viewpoints of having an excellent effect of preventing a decrease in the insulating resistance. When a pigment, a dye, an inorganic filler and the like are incorporated, the amount of incorporation of these components (particularly, the inorganic pigment) is preferably 100 parts or less by mass, more preferably 0.5 parts by mass to 50 parts by mass, and particularly preferably 4 parts by mass to 50 parts by mass, with respect to 100 parts by mass of the ethylene-polar monomer copolymer.

According to the invention, the surface of the back sheet base material formed from a fluoro-resin or a polyester resin on the side where at least a sealing material layer is laminated, is subjected to a chemical treatment or a physical treatment to improve adhesiveness.

Examples of the physical treatment that is applied on the surface of the base material of a polyester resin or a fluoro-resin that constitutes the back sheet, include a corona treatment, a plasma treatment, a flaming treatment and an ozone treatment.

Examples of the chemical treatment include an anchor coating treatment. The amount of the anchor coating agent that is used in the anchor coating treatment is preferably in the range of 1 g/m² to 300 g/m², and more preferably 3 g/m² to 200 g/m², from the viewpoints of obtaining good adhesiveness.

The anchor coating agent is an adhesive or an auxiliary adhesive for increasing the adhesiveness of the base material, and may be appropriately selected from among known materials. Any of a solvent type agent or an aqueous type agent may be selected. According to the invention, a two-liquid reaction type urethane resin-based adhesive is preferable from the viewpoints of obtaining good adhesive power between the base material and the ethylene-polar monomer copolymer.

A two-liquid reaction type urethane resin-based adhesive having excellent resistance to hydrolysis is preferable. As a preferable form of the urethane resin-based adhesive, an adhesive composition obtainable by incorporating a curing agent to the simple substance of any of a polyester urethane polyol produced by subjecting a polyester polyol or a bifunctional or higher-functional isocyanate compound to chain extension, or a mixture thereof, is preferable, or an adhesive composition obtainable by incorporating 1 part by mass to 50 parts by mass of at least one compound selected from a carbodiimide compound, an oxazoline compound and an epoxy compound with respect to 100 parts by mass of this adhesive composition is preferable. When a carbodiimide compound, an oxazoline compound or an epoxy compound is contained, a carboxyl group that may be generated when hydrolysis occurs in a reaction accelerating environment such as high temperature and high humidity, is blocked, and thus a decrease in the adhesiveness due to moisture may be suppressed.

The polyester polyol may be obtained by using at least one of an aliphatic dibasic acid such as succinic acid, glutaric acid, adipic acid, pimellic acid, suberic acid, azelaic acid, sebacic acid or brassylic acid, and an aromatic dibasic acid such as isophthalic acid, terephthalic acid or naphthalenedicarboxylic acid, with at least one of an aliphatic diol such as ethylene glycol, propylene glycol, butanediol, neopentyl glycol, methylpentanediol, hexanediol, heptanediol, octanediol, nonanediol, decanediol or dodecanediol, an alicyclic diol such as cyclohexanediol or hydrogenated xylene glycol, and an aromatic diol such as xylene glycol. Furthermore, a polyester urethane polylol obtained by chain-extending the hydroxyl groups at both ends of the polyester polyol using, for example, a simple substance of an isocyanate compound selected from 2,4- or 2,6-tolylene diisocyanate, xylene diisocyanate, 4,4′-diphenylmethane diisocyanate, methylene diisocyanate, isopropylene diisocyanate, lysine diisocyanate, 2,2,4- or 2,4,4-trimethylhexamethylene diisocyanate, 1,6-hexamethylene diisocyanate, methylcyclohexane diisocyanate, isophorone diisocyanate, 4,4′-dicyclohexylmethane diisocyanate and isopropylidene dicyclohexyl-4,4′-diisocyanate, or an adduct, a biuret form or an isocyanurate form formed from at least one selected from these isocyanate compounds, may be used.

Examples of the polyol component that is considered as a polyurethane-based material include polyether polyol, polycarbonate polyol, and acrylic polyol, and a main agent containing these components may be used. Among them, when heat resistance and the like are considered, polycarbonate polyol or acrylic polyol is preferable.

An isocyanate compound may be used as the curing agent that crosslinks these compounds. However, the curing agent is not limited to these, and any type of curing agent having an active hydrogen group and reactivity may be used.

Examples of the carbodiimide compound that is expected to have an action of blocking the carboxyl group include N,N′-di-o-toluoylcarbodiimide, N,N′-diphenylcarbodiimide, N,N′-di-2,6-dimethylphenylcarbodiimide, N,N′-bis(2,6-diisopropylphenyl)carbodiimide, N,N′-dioctyldecylcarbodiimide, N-toluoyl-N′-cyclohexylcarbodiimide, N,N′-di-2,2-di-tert-butylphenylcarbodiimide, N-toluoyl-N′-phenylcarbodiimide, N,N′-di-p-nitrophenylcarbodiimide, N,N′-di-p-aminophenylcarbodiimide, N,N′-di-p-hydroxyphenylcarbodiimide, N,N′-dicyclohexylcarbodiimide and N,N′-di-p-toluoylcarbodiimide.

Examples of the oxazoline compound that is expected to have the action as described above include monooxazoline compounds such as 2-oxazoline, 2-methyl-2-oxazoline, 2-phenyl-2-oxazoline, 2,5-dimethyl-2-oxazoline, and 2,4-diphenyl-2-oxazline; and dioxazoline compounds such as 2,2′-(1,3-phenylene)-bis(2-oxazoline), 2,2′-(1,2-ethylene)-bis(2-oxazoline), 2,2′-(1,4-butylene)-bis(2-oxazoline), and 2,2′-(1,4-phenylene)-bis(2-oxazoline).

Examples of the epoxy compound that is expected to have the same action as described above include diglycidyl ether of an aliphatic diol such as 1,6-hexanediol, neopentyl glycol or polyalkylene glycol; a polyglycidyl ether of an aliphatic polyol such as sorbitol, sorbitan, polyglycerol, pentaerythritol, diglycerol, glycerol or trimethylolpropane; a polyglycidyl ether of an alicyclic polyol such as cyclohexanedimethanol; a diglycidyl ester or a polyglycidyl ester of an aliphatic or aromatic polyvalent carboxylic acid such as terephthalic acid, isophthalic acid, naphthalenedicarboxylic acid, trimellitic acid, adipic acid or sebacic acid; a diglycidyl ether or a polyglycidyl ether of a polyhydric phenol such as resorcinol, bis-(p-hydroxyphenyl)methane, 2,2-bis-(p-hydroxyphenyl)propane, tris(p-hydroxyphenyl)methane or 1,1,2,2-tetrakis(p-hydroxyphenyl)ethane; a triglycidyl derivative of N,N-diglycidylaniline, N,N-diglycidyltoluidine or aminophenol; trigylcidyl tris(2-hydroxyethyl)isocyanurate, triglycidyl isocyanurate, an orthocresol type epoxy, and a phenol novolac type epoxy.

Among them, the two-liquid reaction type urethane resin-based anchor coating agent is preferably an adhesive composition using a main agent containing polyester urethane polyol and a curing agent containing an isocyanate compound.

When the sealing material layer composed of a resin layer is formed on the back sheet base material, the surface of the back sheet base material that is bonded to the sealing material layer may be subjected in advance to an ozone treatment, a plasma treatment, a corona discharge treatment, a flaming treatment or the like. Among these, a corona discharge treatment is preferably used, from the viewpoints of the convenience of production facilities, an effect of enhancing adhesiveness, and an effect of sustaining adhesiveness.

The method of laminating a sealing material layer containing the ethylene copolymer composition according to the invention on a back sheet base material, may be carried out according to a method of extruding after heating and melting the ethylene copolymer composition in an extruder such as an extrusion laminator or a horizontal T-die extruder, and laminating the composition on the surface of the back sheet base material where a physical treatment or a chemical treatment has been applied. According to a preferable embodiment, a method of applying a corona treatment in advance to the back sheet and then performing lamination is used.

Heating and melting may be carried out so as to satisfy the temperature, viscosity and the like as desired, by taking into consideration the various performances such as fluidity, film-forming property, film thickness adjustment and film thickness uniformity of the ethylene copolymer composition of the invention. The heating temperature of the heating and melting may be selected to be a temperature at which the ethylene copolymer composition enters a molten state, and specifically, the heating temperature is preferably in the range of 100° C. to 300° C., and more preferably in the range of 120° C. to 200° C.

The “molten state” according to the invention means a state in which the resin is softened and exhibits a ductility and a ductibility. When the resin is supplied in this state, the resin is fused on the back sheet base material. “Fusing” means that adhesiveness occurs between the resin and the back sheet base material.

It is preferable to perform the heating and melting process such that the viscosity of the ethylene copolymer composition during melting falls in the range of 50 Pa·s to 500 Pa·s at 160° C. When the viscosity is in the above range, a desired thickness may be selected, and a certain degree of adhesiveness between the protective base materials is obtained. Particularly, it is more preferable to perform the heating and melting process such that the viscosity falls in the range of 100 Pa·s to 450 Pa·s at 160° C.

The viscosity is a value measured at 160° C. using a capillary type rheometer. Specifically, a molten sample in a cylinder at a certain temperature is extruded through a capillary die by a piston, the shear rate and the shear stress at the time of extruding are detected, and thus the molten viscosity is measured.

Supply of a non-crosslinked resin composition that has been heated and melted onto a back sheet in a molten state may be carried out by, for example, an extrusion molding method (for example, T-die extrusion method) such as single-screw extrusion, twin-screw extrusion or co-extrusion, or a calendar method. Specifically, an extruder such as an extrusion laminator or a horizontal T-die extruder may be used to supply the resin composition.

The thickness of the sealing material layer containing the ethylene copolymer composition that is provided on the back sheet, is not particularly limited, but is usually about 0.01 mm to 1.0 mm.

The back sheet of the invention is constructed using a base material using a fluoro-resin or a polyester resin. The fluoro-resin or polyester resin is suitable in terms of weather resistance, heat resistance and insulating properties. A fluoro-resin substrate based mainly on a fluoro-resin, or a polyester resin substrate based mainly on a polyester resin is preferable as the base material. Here, the term “based mainly on” means that the content ratio of the fluoro-resin or polyester resin in the resin substrate is 80% or more by mass.

The fluoro-resin that is suitable for the reason as described above may be, for example, a fluorine-based base material selected from a tetrafluoroethylene-ethylene copolymer (PTFE), a tetrafluoroethylene-hexafluoropropylene copolymer (FEP), a tetrafluoroethylene-perfluoroalkyl vinyl ether copolymer (PFA), polychlorotrifluoroethylene (PCTFE), a chlorotrifluoroethylene-ethylene copolymer (PCTFEE), polyvinyl fluoride (PVF) and polyvinylidene fluoride (PVDF).

The polyester resin that is suitable for the reason as described above may be a polyester-based base material selected from polyethylene terephthalate (PET), polyethylene naphthalate (PEN), polybutylene terephthalate (PBT), and polycyclohexanedimethanol terephthalate (PCT).

As the polyester-based base material, a base material obtainable by using a polybasic acid or an ester-forming derivative thereof and a polyol or an ester-forming derivative thereof may be used. The polyester-based base material may be a polyester obtained from an acid component such as terephthalic acid, isophthalic acid, phthalic acid, phthalic anhydride, 2,6-naphthalenedicarboxylic acid, 1,4-cyclohexanedicarboxylic acid, adipic acid, sebacic acid, trimellitic acid, pyromellitic acid, dimer acid, maleic acid or itaconic acid as the polybasic acid component, and a polyol component such as ethylene glycol, 1,4-butanediol, diethylene glycol, dipropylene glycol, 1,6-hexanediol, 1,4-cyclohexanedimethanol, trimethylolpropane, pentaerythritol, xylene glycol, dimethylolpropane, poly(ethylene oxide) glycol, poly(tetramethylene oxide) glycol, or a polyol component having a carboxylic acid group, a sulfonic acid group or an amino group, or a group derived from salts thereof, as the polyol component. Among these, a polyester obtained from two or more kinds of the polybasic acid component and one or two or more kinds of the polyol component is suitably used, and particularly from the viewpoints of weather resistance or heat resistance, polyethylene terephthalate (PET), polyethylene naphthalate (PEN), polybutylene terephthalate (PBT), and polycyclohexanedimethanol terephthalate (PCT) mentioned above are preferable.

However, the polyester resin base materials, and particularly polyethylene terephthalate and the like, are material having a risk of undergoing hydrolysis. Thus, when a polyester-based base material such as polyethylene terephthalate is used, a hydrolysis-resistant polyester-based base material having a number average molecular weight in the range of 18000 to 40000, a cyclic oligomer content of 1.5% or less by mass, and an intrinsic viscosity of 0.5 dl/g or greater, is preferable.

In the case of such a polyester resin base material, similarly to the case of the polyol as described above, when the molecular terminals have carboxylic acid groups, the polyester resin base material is brought under the action of heat, water and an acid catalyst, and is most affected by hydrolysis. Accordingly, use is made of a solid-state polymerization method capable of increasing the number average molecular weight without increasing the amount of this terminal carboxylic acid, or the terminal carboxylic acid groups may be sealed with a carbodiimide-based compound, an oxazoline-based compound, or an epoxy-based compound. Furthermore, when there is a concern about the shrinking effect of heat during the production of solar cell modules, a polyester base material which has acquired a heat shrinkage ratio of 1% or less, and preferably 0.5% or less, by being subjected to an annealing treatment, may be used. When weather resistance is required, an ultraviolet absorber such as benzophenone, benzotriazole or triazine; a hindered phenol-based, phosphorus-based, sulfur-based or tocopherol-based antioxidant, a hindered amine-based photostabilizer may also be appropriately incorporated.

The back sheet used in the invention may be produced using not only a fluoro-resin or a polyester resin, but also a polycarbonate resin, an acrylic resin, a polyolefin resin, a polyamide resin, a polyarylate resin or the like, laminated on the back sheet so as to adjust heat resistance, strength properties, electrical insulating properties and the like.

When a polyester resin base material is used as the base material contained in the back sheet of the invention, the polyester resin base material may be transparent, but from the viewpoints of enhancing weather resistance and external appearance, a white-colored or black-colored polyester film is preferable. At this time, the white-colored polyester film may be a “pigment dispersion type” in which a white additive such as titanium oxide, silica, alumina, calcium carbonate or barium sulfate has been added; or an “unexpanded type” in which a polymer that is non-compatible with polyester or fine particles are added, and pores are formed at the interface of the blend during biaxial stretching to result in whitening of the blend. In regard to the “unexpanded type”, the “polymer that is non-compatible with polyester” is preferably a polyolefin-based resin such as polyethylene, polypropylene, polybutene or polymethylpentene. If needed, a polyalkylene glycol or a copolymer thereof may be used as a compatibilizing agent. Furthermore, specific examples of the fine particles include organic particles and inorganic particles, and examples thereof include silicone particles, polyimide particles, crosslinked styrene-divinylbenzene copolymer particles, crosslinked polyester particles, and fluorine-based particles. Examples of inorganic particles include particles of calcium carbonate, silicon dioxide and barium sulfate.

Regarding the black-colored polyester film, the “pigment dispersion type” in which a black additive such as carbon black has been added, is used.

When the back sheet has a multilayer structure, a fluoro-resin or a polyester resin may be laminated in any form, and a form in which the fluoro-resin or polyester resin is present on the side brought into contact with the ethylene-based copolymer composition of the invention, is preferable. In general, the following constitution may be employed, but the invention is not limited to these examples.

Examples of the constitution of the base material include fluoro-resin/polyester resin/fluoro-resin, fluoro-resin/aluminum foil/fluoro-resin, polyester resin/aluminum foil/polyester resin, polyester resin/white polyester resin/polyester resin, silica-deposited polyester resin/white polyester resin, and silica-deposited polyester resin/polyester resin/white polyester resin.

The laminated sheet for solar cell of the invention described above, a solar cell element and a transparent protective material such as glass are arranged so as to interpose the solar cell element, and the assembly is fixed by heating and/or pressing. Thereby, a solar cell module may be produced. There are various types of such a solar cell module. An example thereof includes a solar cell module having a laminated structure having a solar cell element interposed between sealing materials on both sides, such as upper transparent protective base material on which sunlight enters/sealing material/solar cell element/laminated sheet for solar cell of the invention as described above.

Another type of solar cell module may have a constitution in which an amorphous solar cell element is formed on a glass substrate by sputtering, and the laminated sheet for solar cell of the invention described above is superimposed thereon such that the sealing material layer faces the solar cell element.

The laminated sheet for solar cell of the invention does not require a sealing material when a solar cell module is produced as described above, if the layer of the ethylene copolymer composition (sealing material layer) has a thickness sufficient to exhibit the performances as a sealing material. However, if the layer of the ethylene copolymer composition is thin, a solar cell module may be produced by a conventional method by providing a separate sealing material. In that case, the sealing material that is provided separately is preferably of the same type as the ethylene copolymer composition of the invention, from the viewpoints of durable adhesiveness.

Examples of the solar cell element include various solar cell elements, for example, silicon-based elements such as single crystal silicon, polycrystalline silicon, and amorphous silicon; and Group III-V or Group II-VI compound semiconductor-based elements such as gallium-arsenic, copper-indium-selenium, and cadmium-tellurium. The laminated sheet for solar cell of the invention described above is particularly useful in the sealing of amorphous solar cell elements, for example, amorphous silicon, from the viewpoints of the durable adhesiveness with the sealing material.

Examples of the upper protective base material that constitutes the solar cell module include glass, an acrylic resin, polycarbonate, polyester, and a fluorine-containing resin, from the viewpoints that the upper protective base material is the incident surface on which sunlight enters.

When the upper protective base material is an acrylic resin, polycarbonate, polyester or a fluorine-containing resin, the laminated sheet for solar cell of the invention may be directly used.

### EXAMPLES

Hereinafter, the invention will be more specifically described with reference to Examples, but the invention is not limited to the following Examples as long as the gist is not departed from.

—1. Raw Materials—

The following materials were prepared to carry out the Examples and Comparative Examples described below. The term “methacrylic acid content” represents the copolymerization ratio of the repeating constituent unit derived from methacrylic acid, and the MFR represents the melt flow rate value measured according to JIS K7210-1999, at 190° C. under a load of 2160 g.

### (1) Resin

Resin (a): Zn ionomer of an ethylene-methacrylic acid copolymer

(Methacrylic acid content: 15% by mass, MFR: 5 g/10 min, degree of neutralization: 23%, melting point: 91° C.)
Resin (b): Zn ionomer of an ethylene-methacrylic acid copolymer

(Methacrylic acid content: 8.7% by mass, MFR: 5.5 g/10 min, degree of neutralization: 17%, melting point: 98° C.)
Resin (c): Ethylene-methacrylic acid copolymer

(Methacrylic acid content: 15% by mass, MFR: 25 g/10 min, melting point: 93° C.)
Resin (d): Ethylene-methacrylic acid copolymer

(Methacrylic acid content: 20% by mass, MFR: 60 g/10 min, melting point: 87° C.)
Resin (e): Na ionomer of an ethylene-methacrylic acid copolymer

(Methacrylic acid content: 15% by mass, MFR: 2.8 g/10 min, degree of neutralization: 30%, melting point: 92° C.)

### (2) Silane Coupling Agent

Silane coupling agent (a): N2-(aminoethyl)-3-aminopropylmethyldimethoxysilane
Silane coupling agent (b): N2-(aminoethyl)-3-aminopropyltrimethoxysilane
Silane coupling agent (c): 3-aminopropyltriethoxysilane
Silane coupling agent (d): 3-glycidoxypropyltrimethoxysilane
Silane coupling agent (e): 3-glycidoxypropylmethyldiethoxysilane

### (3) Antioxidant: Pentaerythritoltetrakis[3-(3,5-di-t-butyl-4-hydroxyphenyl) propionate] (IRGANOX 1010, manufactured by Ciba Specialty Chemicals, Inc.)

### (4) Ultraviolet absorber: 2-Hydroxy-4-n-octoxybenzophenone (CHIMASSORB 81, manufactured by Ciba Specialty Chemicals, Inc.)

### (5) Photostabilizer: Bis(2,2,6,6-tetramethyl-4-piperidyl)sebacate (TINUVIN 770DF, manufactured by Ciba Specialty Chemicals, Inc.)

### (6) Anchor coating agent: Two-liquid reaction type urethane resin-based adhesive manufactured by Dainichiseika Color & Chemicals Mfg. Co., Ltd.

[SEIKADYNE 2810C (main agent)/SEIKADYNE 2710A (curing agent)/ethyl acetate=5/5/50 (mass ratio)]

—2. Base Material—

The following four kinds of base materials were prepared.
Blue plate glass: thickness 3.2 mm, size 7.5 cm×12 cm (manufactured by Asahi Glass Co., Ltd., blue reinforced float plate glass)
White plate glass: thickness 3.2 mm, size 7.5 cm×12 cm (manufactured by Asahi Glass Co., Ltd., white reinforced plate glass)
Back sheet (1): Laminated base material of PVF (polyvinyl fluoride having thickness of 38 μm)/PET (polyethylene terephthalate having thickness of 75 μm)/PVF (polyvinyl fluoride having thickness of 38 μm)

[PTD75 (fluoro-resin base material) manufactured by MA Packaging Co., Ltd.; PVF; TEDLAR (registered trademark) manufactured by Du Pont]

The back sheet (1) was used after being subjected to a corona treatment on the PVF surface so as to adjust the wetting tension to 50 mN/m or higher.
Back sheet (2): Laminated base material of PET (polyethylene terephthalate having thickness of 12 μm)/white PET (white polyethylene terephthalate having thickness of 50 μm)

[Polyester resin base material; TOYAL SOLAR manufactured by Toyo Aluminum K.K.]

The back sheet (2) was used after being subjected to a corona treatment on the surfaces of both sides so as to adjust the wetting tension of the surface to 50 mN/m or higher.

—3. Solar Cell Element—

Polycrystalline silicon type PWP1CP3 manufactured by Photowatt Technologies.

—4. Production of Sealing Sheet—

5000 g of the resin (a), 25 g of the silane coupling agent (a), 1 g of the antioxidant, 10 g of the ultraviolet absorber, and 3.5 g of the photostabilizer were respectively weighed and mixed, and impregnated pellets were produced from the mixture. The resulting impregnated pellets were kneaded at a processing temperature of 180° C. using an extruder (L/D=26, full flight screw, compression ratio 2.6), and the product was melt extruded into a sheet form. Thus, a sealing sheet having a sheet thickness of 0.4 mm was produced.

(Preliminary Experiments 1 to 10)

70 g of the resin indicated in the following Table 1, and similarly, 0.7 g of the silane coupling agent indicated in the following Table 1 were respectively weighed, and these components were mixed in a Labo Plastomill kneading machine (manufactured by Toyo Seiki Co., Ltd., twin-screw) at 150° C. and a speed of rotation of 30 rpm for 15 minutes. At this time, the change in the torque [N·m] was monitored, and thus it was evaluated whether molding was possible by a melt extrusion lamination method. In this process, the silane coupling agent was added after the resin torque after the resin feeding had been stabilized.

The change in torque, ΔN (%), was determined by the following formula, from the maximum value (Nmax) and the minimum value (Nmin) of torque. The results are shown in the following Table 1.

ΔN[%]=(Nmax/Nmin)×100 Formula

TABLE 1

| | | Silane coupling agent | | Torque Change | |
|---|---|---|---|---|---|
| | | | Amount | ΔN and | Suitability to |
| | Resin | Type | added (*1) | Observation | lamination molding |
| Preliminary | Resin | Silane Coupling | 1 part | 100% | Lamination possible |
| Experiment 1 | (a) | Agent (a) | | | |
| Preliminary | Resin | Silane Coupling | 1 part | 103% | Lamination possible |
| Experiment 2 | (b) | Agent (a) | | | |
| Preliminary | Resin | Silane Coupling | 1 part | 168%, Gelled | Lamination |
| Experiment 3 | (a) | Agent (b) | | | impossible |
| Preliminary | Resin | Silane Coupling | 1 part | 192%, Gelled | Lamination |
| Experiment 4 | (a) | Agent (c) | | | impossible |
| Preliminary | Resin | Silane Coupling | 1 part | 186%, Gelled | Lamination |
| Experiment 5 | (a) | Agent (d) | | | impossible |
| Preliminary | Resin | Silane Coupling | 1 part | 236%, Gelled | Lamination |
| Experiment 6 | (a) | Agent (e) | | | impossible |
| Preliminary | Resin | Silane Coupling | 1 part | 255%, Gelled | Lamination |
| Experiment 7 | (b) | Agent (c) | | | impossible |
| Preliminary | Resin | Silane Coupling | 1 part | 239%, Gelled | Lamination |
| Experiment 8 | (c) | Agent (c) | | | impossible |
| Preliminary | Resin | Silane Coupling | 1 part | 232%, Gelled | Lamination |
| Experiment 9 | (d) | Agent (c) | | | impossible |
| Preliminary | Resin | Silane Coupling | 1 part | 220%, Gelled | Lamination |
| Experiment 10 | (e) | Agent (c) | | | impossible |

(*1): Amount of addition based on 100 parts of the resin

As can be seen from the results of the Table 1, the coupling agents other than the dialkoxysilane having an amino group underwent gelation as a result of melt kneading, and had large changes in the torque. Thus, it was found that extrusion lamination molding could not be achieved.

From the results above, the examples of using the resins (a) to (b) and the silane coupling agent (a) will be shown as Examples. In addition, the formation of laminated sheets using the compositions of the preliminary experiments 3 to 10 was difficult.

### Example 1

### Application of Anchor Coating Agent

The back sheet (2) was used, and the anchor coating agent was applied on the surface of the white PET by selecting a bar coater No. 8. Subsequently, the anchor coating agent was dried at 100° C. for 5 minutes. At this time, the coating thickness after drying was 1 μm or less. A laminated sheet for solar cell was produced as described below, using the base material thus obtained.

—Production of Laminated Sheet for Solar Cell—

5000 g of the resin (a), 25 g of the silane coupling agent (a), 1 g of the antioxidant, 10 g of the ultraviolet absorber, 3.5 g of the photostabilizer, and 100 g of a white pigment (titanium oxide, R103 manufactured by DuPont Company) (concentration 60% by mass) were respectively weighed and mixed, and thus impregnated pellets were obtained. The resulting impregnated pellets were kneaded at a processing temperature of 180° C. using an extruder (L/D=26, full flight screw, compression ratio 2.6), and the molten resin was laminated on the anchor-coated surface of the back sheet (2) that had been arranged such that the anchor-coated surface faced the molten resin, to obtain a thickness of the melt extruded resin of 0.1 mm. Thus, a resin layer (sealing material layer) was formed. Thereafter, the laminated sheet was aged for 48 hours at 40° C. As such, a laminated sheet A for solar cells was produced, and thus a solar cell module was produced.

—Evaluation—

The laminated sheet A for solar cells that was obtained as described above was evaluated as follows. The evaluation results are shown in the following Table 2.

(1) Durability

Laminated samples were produced under the following conditions, and the initial yellow index YI was measured using a color computer SM-T (manufactured by Suga Test Instruments Co., Ltd.).

<Conditions>
Pasting apparatus: LM-50×50S manufactured by NPC Corp.
Sample composition: Blue glass/aforementioned sealing sheet/laminated sheet A for solar cells
Pasting conditions: Pasting at 150° C.×10 min

Subsequently, the samples were respectively subjected to aging under the following environmental conditions according to the evaluation items, using Ci-4000 (manufactured by Atlas Material Testing Technology LLC), and then the YI was measured again in the same manner as described above. The degree of yellowing was evaluated by comparing the YI value with the initial YI value. A smaller change in the YI values measured before and after aging means excellent durability.
Heat resistance: 85° C.×1000 hours
Moisture resistance: 85° C.×90% RH×1000 hours
Weather resistance: 83° C.×180 W/m²×50% RH×1000 hours

(2) Adhesiveness Between Anchor-Coating Treated Surface of Back Sheet and Resin Layer

Each of the laminated samples, for which the various evaluation items of the evaluation in the above “(1) Durability” had been completed, was cut to a width of 10 mm, and the adhesion strength [N] between the anchor-coated surface of the back sheet and the resin layer was measured at a tensile speed of 50 mm/min, by peeling between the back sheet and the resin layer of each of the obtained sample specimens. An allowable range of the adhesion strength is 2 N or greater.

(3) Adhesiveness Between Sheet for Sealing Material and Glass

A laminated sample was produced in the same manner as in the above “(1) Durability”, and this laminated sample was cut to a width of 10 mm. The adhesion strength [N] between the blue plate glass and the sealing sheet of the sample was measured at a tensile speed of 50 mm/min, by peeling between the sealing sheet and glass of the obtained sample specimen. An allowable range of the adhesion strength is 10 N or greater.

—Production of Solar Cell Module—

The laminated sheet A for solar cell thus obtained was used, and this was heated to melt the resin layer. Then, blue plate glass/sealing sheet/solar cell element/laminated sheet A for solar cell (=sealing material layer/back sheet (2)) were stacked in this order of lamination and pressed, and thus a solar cell module was produced.

### Example 2

5000 g of the resin (b), 25 g of the silane coupling agent (a), 1 g of the antioxidant, 10 g of the ultraviolet absorber, and 3.5 g of the photostabilizer were incorporated, and thus impregnated pellets were obtained. The resulting impregnated pellets were kneaded at a processing temperature of 180° C. using an extruder (L/D=26, full flight screw, compression ratio 2.6), and the molten resin was laminated on the corona-treated surface of the back sheet (2) that had been subjected to a corona treatment in advance, to obtain a thickness of the melt extruded resin of 0.2 mm. Thus, a resin layer (sealing material layer) was formed. As such, a laminated sheet B for solar cell was produced. White plate glass/solar cell element/laminated sheet B for solar cell (=sealing material layer/back sheet (2)) were stacked, and thus a solar cell module was produced. The evaluation results are shown in the following Table 2.

### Example 3

A laminated sheet C for solar cell was produced in the same manner as in Example 2, except that the impregnated pellets were commuted to the two kinds of mixtures as described below and the molten resin was extrusion coated in three stacked layers on the corona-treated surface of the back sheet (2), and thus a resin layer (sealing material layer) having a trilayer structure was formed to be used as a laminated sheet. Evaluation of the laminated sheet C was performed. At this time, the thicknesses of the outer layer 1, the middle layer and the outer layer 2 were adjusted to 50 μm, 100 μm and 50 μm, respectively. Furthermore, white plate glass/solar cell element/laminated sheet C for solar cells (=sealing material layer/back sheet (2)) were stacked, and a solar cell module was produced in the same manner as in Example 2. The evaluation results are shown in the following Table 2.

<Outer Layer 1>

Impregnated pellets prepared in the same manner as in Example 2

<Middle Layer>

Impregnated pellets prepared in the same manner as in Example 2, except that the silane coupling agent was excluded from the impregnated pellets

<Outer Layer 2>

Impregnated pellets prepared in the same manner as in Example 1

### Example 4

5000 g of the resin (b), 25 g of the silane coupling agent (a), 1 g of the antioxidant, 10 g of the ultraviolet absorber, and 3.5 g of the photostabilizer were mixed, and thus impregnated pellets were obtained. The resulting impregnated pellets were kneaded at a processing temperature of 180° C. using an extruder (L/D=26, full flight screw, compression ratio 2.6), and the molten resin was laminated on the corona-treated surface of the back sheet (1) that had been subjected to a corona treatment in advance, to obtain a thickness of the melt extruded resin of 0.2 mm. Thus, a resin layer (sealing material layer) was formed. As such, a laminated sheet D for solar cells was produced. White plate glass/solar cell element/laminated sheet D for solar cells (=sealing material layer/back sheet (1)) were stacked, and thus a solar cell module was produced. The evaluation results are shown in the following Table 2.

TABLE 2

| | | Durability evaluation | | | | | | |
|---|---|---|---|---|---|---|---|---|
| | Adhesiveness | Heat resistance | | | Moisture resistance | | | |
| | between sealing | Initial | After lapse | Adhesion | Initial | After lapse | Adhesion | Weather resistance |
| | sheet/glass | value | of 1000 | strength | value | of 1000 | strength^{(*1)} | Adhesion strength^{(*1)} |
| | [N/10 mm] | (YI) | hours (YI) | [N/10 mm]^{(*1)} | (YI) | hours (YI) | [N/10 mm] | [N/10 mm] |
| Example 1 | >40 | −2.9 | −2.4 | >3 (Material | −2.5 | −1.3 | >3 (Material | >3 (Material |
| | (Sheet break) | | | destruction) | | | destruction) | destruction) |
| Example 2 | 25 | −6.2 | −10 | >3 (Material | −6.2 | −8 | >3 (Material | >3 (Material |
| | | | | destruction) | | | destruction) | destruction) |
| Example 3 | 25 | −6 | −9.6 | >3 (Material | −6.4 | −7.7 | >3 (Material | >3 (Material |
| | | | | destruction) | | | destruction) | destruction) |
| Example 4 | 25 | 2.8 | −1 | >10 (Material | 2.8 | 1 | >10 (Material | >10 (Material |
| | | | | destruction) | | | destruction) | destruction) |

^{*1}Adhesion strength between anchor-coated surface and resin layer (sealing material layer)

The entire disclosure of Japanese Patent Application No. 2008-166959 and 2009-080157 is incorporated herein into this specification by reference.

All documents, patent applications and technical specifications recited in this specification are incorporated herein by reference in this specification to the same extent as if each individual publication, patent applications and technical standard was specifically and individually indicated to be incorporated by reference.

1. A laminated sheet for a solar cell, the laminated sheet comprising a back sheet base material including a fluoro-resin or a polyester resin, a sealing material layer being laminated on a surface of the back sheet base material where a chemical treatment or a physical treatment for improving adhesiveness has been applied by a melt extrusion lamination method, the sealing material layer comprising an ethylene copolymer composition that includes a dialkoxysilane having an amino group, and a copolymer of ethylene and a polar monomer that has a polar group selected from a carboxylic acid group and a group derived from a carboxylate.

2. The laminated sheet for a solar cell according to claim 1, wherein the chemical treatment includes coating of a two-liquid reaction type urethane resin-based anchor coating agent.

3. The laminated sheet for a solar cell according to claim 2, wherein the urethane resin-based anchor coating agent is a two-liquid reaction type adhesive composition which includes a main agent comprising a polyester urethane polyol and a curing agent comprising an isocyanate compound.

4. The laminated sheet for a solar cell according to claim 1, wherein the physical treatment is a corona treatment.

5. The laminated sheet for a solar cell according to claim 1, wherein the copolymer of ethylene and a polar monomer is at least one of an ethylene-unsaturated carboxylic acid copolymer or an ionomer of an ethylene-unsaturated carboxylic acid copolymer.

6. The laminated sheet for a solar cell according to claim 1, wherein the dialkoxysilane is at least one of 3-aminopropylalkyldialkoxysilane or N2-(aminoethyl)-3-aminopropylalkyldialkoxysilane.

7. The laminated sheet for a solar cell according to claim 1, wherein a content ratio of the dialkoxysilane is 15 parts or less by mass with respect to 100 parts by mass of the copolymer of ethylene and a polar monomer.

8. The laminated sheet for a solar cell according to claim 5, wherein the ethylene-unsaturated carboxylic acid copolymer is an ethylene-acrylic acid copolymer or an ethylene-methacrylic acid copolymer.

9. The laminated sheet for a solar cell according to claim 5, wherein the ionomer is a zinc ionomer of an ethylene-unsaturated carboxylic acid copolymer.

10. The laminated sheet for a solar cell according to claim 5, wherein the ionomer has a degree of neutralization with respect to acid groups in the ethylene-unsaturated carboxylic acid copolymer of 60% or less.

11. The laminated sheet for a solar cell according to claim 5, wherein, in the ethylene-unsaturated carboxylic acid copolymer, a proportion of a constituent unit derived from an unsaturated carboxylic acid is 20% or less by mass with respect to a total mass of the copolymer.

12. The laminated sheet for a solar cell according to claim 1, wherein a content of the dialkoxysilane is from 0.03 parts by mass to 12 parts by mass with respect to 100 parts by mass of the ethylene-polar monomer copolymer.

13. The laminated sheet for a solar cell according to claim 1, wherein the fluoro-resin is at least one of a tetrafluoroethylene-ethylene copolymer, a tetrafluoroethylene-hexafluoropropylene copolymer, a tetrafluoroethylene-perfluoroalkyl vinyl ether copolymer, polychlorotrifluoroethylene, a chlorotrifluoroethylene-ethylene copolymer, polyvinyl fluoride, or polyvinylidene fluoride.

14. The laminated sheet for a solar cell according to claim 1, wherein the polyester resin is at least one of a polyethylene terephthalate (PET), a polyethylene naphthalate (PEN), a polybutylene terephthalate (PBT), or a polycyclohexanedimethanol terephthalate (PCT).

15. A solar cell module comprising:
a substrate on which sunlight enters;
a solar cell element; and
the laminated sheet for a solar cell according to claim 1.
